(19) United States
(12) Patent Application Publication
(10) Pub. No.: US 2025/0210573 A1
(43) Pub. Date: Jun. 26, 2025

(54) METAL SINTERING PREPARATION AND THE USE THEREOF FOR THE CONNECTING OF COMPONENTS

(71) Applicant: Heraeus Electronics GmbH & Co. KG, Hanau (DE)

(72) Inventors: Wolfgang SCHMITT, Rodgau (DE); Thomas KREBS, Mömbris (DE); Michael SCHÄFER, Künzell (DE); Susanne Klaudia DUCH, Bruchköbel (DE); Jens NACHREINER, Schlüchtern (DE)

(21) Appl. No.: 19/069,858

(22) Filed: Mar. 4, 2025

Related U.S. Application Data
(63) Continuation of application No. 18/235,181, filed on Aug. 17, 2023.
Application No. 18/235,181 is a continuation of application No. 17/331,361, filed on May 26, 2021, now abandoned.
Application No. 17/331,361 is a continuation of application No. 15/523,830, filed on May 2, 2017, now abandoned.

(30) Foreign Application Priority Data
Nov. 3, 2014 (EP) 14191408.5

(51) Int. Cl. H01L 23/00; B22F 1/05; B22F 1/068; B22F 1/102; B22F 3/10; B22F 7/06; B22F 7/08; C22C 5/00; C22C 5/06; C22C 9/00; C22C 21/00

(52) U.S. Cl. CPC H01L 24/29; B22F 1/05; B22F 1/068; B22F 1/102; B22F 3/10; B22F 7/062; B22F 7/064; B22F 7/08; C22C 5/06; H01L 24/27; H01L 24/83; B22F 2301/255; C22C 5/00; C22C 9/00; C22C 21/00; H01L 2224/27505; H01L 2224/29224; H01L 2224/29239; H01L 2224/29244; H01L 2224/29247; H01L 2224/29255; H01L 2224/29264; H01L 2224/29269; H01L 2224/29294; H01L 2224/29324; H01L 2224/29339; H01L 2224/29344; H01L 2224/29347; H01L 2224/29355; H01L 2224/29364; H01L 2224/29369; H01L 2224/32145; H01L 2224/8384

(57) ABSTRACT

A metal sintering preparation containing (A) 50 to 90% by weight of at least one metal that is present in the form of particles having a coating that contains at least one organic compound, and (B) 6 to 50% by weight organic solvent. The mathematical product of tamped density and specific surface of the metal particles of component (A) is in the range of 40,000 to 80,000 cm⁻¹.

### CROSS-REFERENCE TO RELATED APPLICATIONS

This application is a continuation of co-pending U.S. patent application Ser. No. 18/235,181, filed Aug. 17, 2023, which is a continuation of U.S. patent application Ser. No. 17/331,361, filed May 26, 2021, which is a continuation of Ser. No. 15/523,830, filed May 2, 2017, which is a Section 371 of International Application No. PCT/EP2015/060249, filed May 8, 2015, which was published in the German language on May 12, 2016 under International Publication No. WO 2016/071005 A1, which claims priority under 35 U.S.C. § 119(b) to European Application No. 14 191 408.5, filed Nov. 3, 2014, and the disclosure of each of which is incorporated herein by reference.

### BACKGROUND OF THE INVENTION

The present invention relates to a metal sintering preparation and to a method for the connecting of components in which this metal sintering preparation is used.

In power and consumer electronics, the connecting of components, such as LEDs or very thin silicon chips that are highly pressure and temperature sensitive, is particularly challenging.

For this reason, these pressure- and temperature-sensitive components are often connected to each other by gluing. However, adhesive technology is associated with a disadvantage in that it produces contact sites between the components that provide only insufficient heat conductivity and/or electrical conductivity.

In order to solve this problem, the components to be connected are often subjected to sintering. Sintering technology is a very simple method for the connecting of components in a stable manner.

It is known in power electronics to use metal sintering preparations in a sintering process to connect components. For example, WO2011/026623 A1 discloses a metal sintering paste containing 75 to 90% by weight (percent by weight) of at least one metal that is present in the form of particles that comprise a coating which contains at least one organic compound, 0 to 12% by weight of at least one metal precursor, 6 to 20% by weight of at least one solvent, and 0.1 to 15% by weight of at least one sintering aid, as well as the use of this metal sintering preparation to connect components by a sintering method.

### BRIEF SUMMARY OF THE INVENTION

It is the object of the invention to provide a sintering method for the connecting of components in a stable manner. The method is used to produce contact sites of low porosity and high electrical and thermal conductivity between the components to be connected.

It is another object of the present invention to provide a metal sintering preparation that is well-suited for implementing this sintering method.

The invention relates to a method for the connecting of components, which comprises providing (a) a sandwich arrangement that comprises at least (a1) one component 1, (a2) one component 2, and (a3) a metal sintering preparation that is situated between component 1 and component 2, and (b) sintering the sandwich arrangement, wherein the metal sintering preparation comprises (A) 50 to 90% by weight of at least one metal that is present in the form of particles which comprise a coating containing at least one organic compound, and (B) 6 to 50% by weight organic solvent, characterized in that the mathematical product of tamped density and specific surface of the metal particles of component (A) is in the range of 40,000 to 80,000 cm⁻¹.

The invention further relates to metal sintering preparation that comprises (A) 50 to 90% by weight of at least one metal that is present in the form of particles which comprise a coating containing at least one organic compound, and (B) 6 to 50% by weight organic solvent, characterized in that the mathematical product of tamped density and specific surface of the metal particles of component (A) is in the range of 40,000 to 80,000 cm⁻¹.

### DETAILED DESCRIPTION OF THE INVENTION

The tamped density is defined as the density after further compaction by tamping or shaking of a solid as compared to the bulk density. The tamped density in g/cm³ is determined in accordance with DIN EN ISO 787-11:1995-10 (earlier version: (DIN 53194).

The specific surface in m²/g as determined by BET measurement in accordance with DIN ISO 9277:2014-01 (in accordance with chapter 6.3.1, statistical-volumetric measuring procedure, using the gas nitrogen).

The metal sintering preparation according to the invention, in a first embodiment, contains 50 to 90% by weight, for example 77 to 89% by weight, more preferably 78 to 87% by weight, and even more preferably 78 to 86% by weight, and, in a second embodiment, for example 50 to 80% by weight, and more preferably 55 to 75% by weight, of at least one metal that is present in the form of particles comprising a coating that contains at least one organic compound. The weights given presently include the weight of the coating compounds situated on the particles.

The term “metal” used in the context of coated metal particles includes both pure metals and metal alloys.

In the scope of the invention, the term “metal” refers to elements in the periodic system of the elements that are in the same period as boron, but to the left of boron, in the same period as silicon, but to the left of silicon, in the same period as germanium, but to the left of germanium, and in the same period as antimony, but to the left of antimony, as well as all elements having an atomic number of more than 55.

In the scope of the invention, pure metals shall be understood to be metals containing a metal at a purity of at least 95% by weight, preferably at least 98% by weight, more preferably at least 99% by weight, and even more preferably at least 99.9% by weight.

According to a preferred embodiment, the metal is copper, silver, gold, nickel, palladium, platinum, or aluminum, in particular silver.

Metal alloys shall be understood to be metallic mixtures of at least two components of which at least one is a metal.

According to a preferred embodiment, an alloy containing copper, aluminum, nickel and/or precious metals is used as metal alloy.

The metal alloy preferably comprises at least one metal selected from the group consisting of copper, silver, gold, nickel, palladium, platinum, and aluminum. Particularly preferred metal alloys contain at least two metals selected from the group consisting of copper, silver, gold, nickel, palladium, platinum, and aluminum.

Moreover, it can be preferred that the fraction of metals selected from the group consisting of copper, silver, gold, nickel, palladium, platinum, and aluminum accounts for at least 90% by weight, more preferably at least 95% by weight, and even more preferably at least 99% by weight of the metal alloy. The alloy can be, for example, an alloy that contains copper and silver, copper, silver and gold, copper and gold, silver and gold, silver and palladium, platinum and palladium, or nickel and palladium.

The metal sintering preparation according to the invention can contain, as metal, a pure metal, multiple types of pure metal, a type of metal alloy, multiple types of metal alloys or mixtures thereof.

The metal is present in the metal sintering preparation in the form of particles.

The metal particles can differ in shape. The metal particles can be present, for example, in the form of flakes, as irregularly-shaped particles, or may be of a spherical (ball-like) shape. According to a particularly preferred embodiment, the metal particles take the shape of flakes or have an irregular shape. However, this does not exclude a minor fraction of the particles employed being of different shape. However, preferably at least 70% by weight, more preferably at least 80% by weight, even more preferably at least 90% by weight or 100% by weight, of the particles are present in the form of flakes.

It has been found, surprisingly, that the solidity of sintering compounds produced using the metal sintering preparation according to the invention is particularly large or, in other words, the bonding between components bonded by sintering using the metal sintering preparation according to the invention is particularly pronounced. It is therefore essential to the invention that the mathematical product of tamped density and specific surface of the metal particles of component (A) is in the range of 40,000 to 80,000 cm⁻¹, preferably 50,000 to 70,000 cm⁻¹.

In other words, the metal particles of component (A) must be selected by their tamped density and/or their specific surface such that the mathematical product of tamped density and specific surface is a value in the range of 40,000 to 80,000 cm⁻¹. The essential feature of the invention, namely that the mathematical product of tamped density and specific surface of the metal particles of component (A) is in the range of 40,000 to 80,000 cm⁻¹, refers to the entirety of the metal particles of component (A). For example, component (A) of the metal sintering preparation according to the invention can comprise just one type of metal particles, which are characterized by a tamped density and a specific surface that yield a value in the range of 40,000 to 80,000 cm⁻¹ upon calculation of the product of these two parameters. If component (A) of the metal sintering preparation according to the invention comprises two or more different types of metal particles, the quantitative fraction of the individual types must be selected as a function of their respective tamped density and specific surface such that the entirety of the metal particles of component (A) meets the feature that is essential to the invention. This can be attained in one of two ways. The combination of different types of metal particles can be produced, by type and quantity, can then be mixed homogeneously, the tamped density and the specific surface of the mixture can be measured, and then the product of tamped density and specific surface thus determined can be calculated. As an alternative with an equivalent result, one can use known values for tamped density and specific surface of the different types of metal particles, for example the corresponding manufacturers' information, to mathematically determine the product of tamped density and specific surface.

The metal particles are coated. The term “coating of particles” shall be understood to refer to a firmly adhering layer on the surface of particles. The coating of the metal particles contains at least one type of coating compound. These coating compounds are organic compounds. The organic compounds serving as coating compounds are carbon-containing compounds that prevent the metal particles from agglomerating.

According to a preferred embodiment, the coating compounds bear at least one functional group. Conceivable functional groups include, in particular, carboxylic acid groups, carboxylate groups, ester groups, keto groups, aldehyde groups, amino groups, amide groups, azo groups, imide groups or nitrile groups. Carboxylic acid groups and carboxylic acid ester groups are preferred functional groups. The carboxylic acid group can be deprotonated.

The coating compounds with at least one functional group are preferably saturated, mono-unsaturated or multi-unsaturated organic compounds.

Moreover, these coating compounds with at least one functional group can be branched or non-branched. The coating compounds with at least one functional group preferably comprise 1 to 50, more preferably 2 to 24, even more preferably 6 to 24, and yet more preferably 8 to 20 carbon atoms.

The coating compounds can be ionic or non-ionic.

It is preferable to use free fatty acids, fatty acid salts or fatty acid esters as coating compounds. The free fatty acids, fatty acid salts, and fatty acid esters are preferably non-branched. Moreover, the free fatty acids, fatty acid salts, and fatty acid esters preferably are saturated.

Preferred fatty acid salts include the ammonium, monoalkylammonium, dialkylammonium, trialkylammonium, aluminium, copper, lithium, sodium, and potassium salts.

Alkyl esters, in particular methyl esters, ethyl esters, propyl esters, and butyl esters, are preferred esters.

According to a preferred embodiment, the free fatty acids, fatty acid salts or fatty acid esters are compounds with 8 to 24, more preferably 10 to 24, and even more preferably 12 to 18 carbon atoms.

Preferred coating compounds include caprylic acid (octanoic acid), capric acid (decanoic acid), lauric acid (dodecanoic acid), myristic acid (tetradecanoic acid), palmitic acid (hexadecanoic acid), margaric acid (heptadecanoic acid), stearic acid (octadecanoic acid), arachinic acid (eicosanoic acid/icosanoic acid), behenic acid (docosanoic acid), lignoceric acid (tetracosanoic acid) as well as the corresponding esters and salts.

Particularly preferred coating compounds include dodecanoic acid, octadecanoic acid, aluminum stearate, copper stearate, sodium stearate, potassium stearate, sodium palmitate, and potassium palmitate.

The coating compounds can be applied to the surface of the metal particles by conventional methods that are known from the prior art.

It is possible, for example, to slurry the coating compounds, in particular the stearates or palmitates mentioned above, in solvents and to triturate the slurried coating compounds together with the metal particles in ball mills. After trituration, the metal particles, which are coated with the coating compounds, are dried and then dust is removed.

Preferably, the fraction of organic compounds, in particular the fraction of compounds selected from the group consisting of free fatty acids, fatty acid salts or fatty acid esters with 8 to 24, more preferably 10 to 24, and even more preferably 12 to 18 carbon atoms, of the entire coating is at least 60% by weight, more preferably at least 70%, even more preferably at least 80% by, yet more preferably at least 90% by weight, in particular at least 95% by weight, at least 99% by weight or 100% by weight.

Usually, the fraction of the coating compounds, preferably of the coating compounds selected from the group consisting of free fatty acids, fatty acid salts or fatty acid esters with 8 to 24, more preferably 10 to 24, and even more preferably 12 to 18 carbon atoms, is 0.01 to 2% by weight, preferably 0.3 to 1.5% by weight, with respect to the weight of the coated metal particles.

The degree of coating, defined as the ratio of the mass of coating compounds and the surface of the metal particles, is preferably 0.00005 to 0.03 g, more preferably 0.0001 to 0.02 g of coating compounds per square meter (m²) of surface area of the metal particles.

The metal sintering preparation according to the invention contains 6 to 50% by weight, in the first embodiment mentioned above for example 7 to 25% by weight, more preferably 8 to 20% by weight, and in the second embodiment mentioned above for example 15 to 40% by weight, more preferably 15 to 35% by weight organic solvent, i.e., one or more organic solvents. This concerns, in particular, organic solvents that are commonly used for metal sintering preparations. Examples include terpineols, N-methyl-2-pyrrolidone, ethylene glycol, dimethylacetamide, 1-tridecanol, 2-tridecanol, 3-tridecanol, 4-tridecanol, 5-tridecanol, 6-tridecanol, isotridecanol, with the exception of a methyl substitution on the penultimate C-atom, unsubstituted 1-hydroxy-C16-C20-alkanes such as 16-methylheptadecan-1-ol, dibasic esters (preferably dimethylesters of glutaric, adipic or succinic acid or mixtures thereof), glycerol, diethylene glycol, triethylene glycol, and aliphatic hydrocarbons, in particular saturated aliphatic hydrocarbons, having 5 to 32 C-atoms, more preferably 10 to 25 C-atoms, and even more preferably 16 to 20 C-atoms. These aliphatic hydrocarbons are being marketed, for example, by Exxon Mobil by the brand name Exxsol D120 or by the brand name Isopar M.

The metal sintering preparation according to the invention can contain 0 to 12% by weight, preferably 0.1 to 12% by weight, more preferably 1 to 10% by weight, and even more preferably 2 to 8% by weight of at least one metal precursor (C).

In the scope of the invention, a metal precursor shall be understood to mean a compound that contains at least one metal. Preferably, this compound decomposes at temperatures below 200° C. while releasing a metal. Accordingly, the use of a metal precursor in the sintering process is preferably associated with the in situ production of a metal. It is easy to determine whether a compound is a metal precursor. For example, a paste containing a compound to be tested can be deposited on a substrate having a silver surface, followed by heating to 200° C. and maintaining this temperature for 20 minutes. Then, it is determined whether or not the compound to be tested decomposed under these conditions. For this purpose, for example, the content of the metal-containing paste components can be weighed before the test to calculate the theoretical mass of metal. After the test, the mass of the material deposited on the substrate is determined by gravimetric methods. If the mass of the material deposited on the substrate is equal to the theoretical mass of metal, taking into account the usual measuring inaccuracy, the tested compound is a metal precursor.

According to a preferred embodiment, the metal precursor is a metal precursor that can be decomposed endothermically. A metal precursor that can be decomposed endothermically shall be understood to be a metal precursor whose thermal decomposition, preferably in a protective gas atmosphere, is an endothermic process. This thermal decomposition is to be associated with the release of metal from the metal precursor.

According to another preferred embodiment, the metal precursor comprises a metal that is also present in the particulate metal (A).

The metal precursor preferably comprises, as metal, at least one element selected from the group consisting of copper, silver, gold, nickel, palladium, and platinum.

It can be preferred to use, as metal precursor, endothermically decomposable carbonates, lactates, formates, citrates, oxides or fatty acid salts, preferably fatty acid salts having 6 to 24 carbon atoms, of the metals specified above.

In specific embodiments, silver carbonate, silver (I) lactate, silver (II) formate, silver citrate, silver oxide (for example AgO or Ag₂O), copper (II) lactate, copper stearate, copper oxides (for example Cu₂O or CuO) or gold oxides (for example Au₂O or AuO) are used as metal precursor.

According to a particularly preferred embodiment, silver carbonate, silver (I) oxide or silver (II) oxide is used as metal precursor.

The metal precursor, if present in the metal sintering preparation, is preferably present in the form of particles.

The metal precursor particles can take the shape of flakes, irregular shape or a spherical (ball-like) shape. Preferably, the metal precursor particles are present in the form of flakes or as irregularly shaped particles.

Moreover, the metal sintering preparation according to the invention can contain 0 to 10% by weight, preferably 0 to 8% by weight, of at least one sintering aid (D). Examples of sintering aids include organic peroxides, inorganic peroxides, and inorganic acids, such as are described, for example, in WO2011/026623 A1.

Aside from components (A) to (D) illustrated above, the metal sintering preparation according to the invention can contain one or more further ingredients (E), with the total quantity ranging from 0 to 15% by weight, preferably 0 to 10% by weight, more preferably 0.1 to 5% by weight.

These further ingredients can preferably be ingredients that are used commonly in metal sintering preparations. The metal sintering preparation can contain, for example, as further ingredients, dispersion agents, surfactants, de-foaming agents, binding agents, polymers such as cellulose derivatives, for example methylcellulose, ethylcellulose, ethylmethylcellulose, carboxycellulose, hydroxypropylcellulose, hydroxyethylcellulose, hydroxymethylcellulose and/or viscosity-controlling (rheological) agents.

The % by weight fractions specified for ingredients (A) to (E) can add up, for example, to 100% by weight with respect to the metal sintering preparation according to the invention, i.e., prior to the application thereof. Accordingly, the metal sintering preparation according to the invention can be produced by mixing ingredients (A) to (E). Devices known to a person skilled in the art, such as stirrers and three-roller mills, can be used in this context.

The metal sintering preparation according to the invention can be used in a sintering process. Sintering shall be understood to mean the connecting of two or more components by heating without the metal particles (A) reaching the liquid phase.

The sintering method implemented through the use of the metal sintering preparation according to the invention can be implemented while applying pressure or without pressure. Being able to implement the sintering method without pressure means that a sufficiently firm connection of components is attained despite foregoing the application of pressure. Being able to implement the sintering process without pressure allows pressure-sensitive, for example fragile components or components with a mechanically sensitive micro-structure, to be used in the sintering method. Electronic components that have a mechanically sensitive micro-structure suffer electrical malfunction when exposed to inadmissible pressure.

Connecting at least two components shall be understood to mean attaching a first component on a second component. In this context, “on” simply means that a surface of the first component is being connected to a surface of the second component regardless of the relative disposition of the two components or of the arrangement containing the at least two components.

In the scope of the invention, the term “component” preferably comprises single parts. Preferably, these single parts cannot be disassembled further.

According to specific embodiments, the term “components” refers to parts that are used in electronics.

Accordingly, the components can be, for example, diodes, LEDs (light-emitting diodes, lichtemittierende Dioden), DCB (direct copper bonded) substrates, DAB (direct aluminum bonded) substrates, AMB (active metal brazed) substrates, lead frames, dies, IGBTs (insulated-gate bipolar transistors, Bipolartransistoren mit isolierter Gate-Elektrode), ICs (integrated circuits, integrierte Schaltungen), sensors, heat sink elements (preferably aluminum heat sink elements or copper heat sink elements) or other passive components (such as resistors, capacitors or coils).

The components to be connected can be identical or different components.

Embodiments of the invention relate to the connecting of LED to lead frame, LED to ceramic substrate, of dies, diodes, IGBTs or ICs to lead frames, ceramic substrates, DCB, DAB or AMB substrates, of sensor to lead frame or ceramic substrate. The connection can involve aluminum, copper or silver contact surfaces of the electronics components to aluminum, copper or silver contact surfaces of the substrates, i.e., for example aluminum-copper, aluminum-silver, aluminum-aluminum, copper-silver, copper-copper or silver-silver connections can be formed.

The terms “aluminum, copper, and silver contact surfaces” used herein include contact surfaces made of aluminum, copper, and silver alloys.

The components, for example at least one of components 1 and 2 can—in as far as they do not consist of metal anyway-comprise at least one metal contact surface, for example in the form of a metallization layer, for example made of a non-precious metal such as copper or aluminum, by means of which the previously mentioned sandwich arrangement is effected in the scope of the method according to the invention. This metallization layer is preferably part of the component. Preferably, this metallization layer is situated at least at one surface of the component.

Preferably, the connecting of the components by the metal sintering preparation according to the invention is effected by these metallization layer or layers.

The metallization layer can comprise pure metal. Accordingly, it can be preferred for the metallization layer to comprise at least 50% by weight, more preferably at least 70% by weight, even more preferably at least 90% by weight or 100% by weight of pure metal. The pure metal is selected, for example, from the group consisting of aluminum, copper, silver, gold, palladium, and platinum.

On the other hand, the metallization layer can just as well comprise an alloy. The alloy of the metallization layer preferably contains at least one metal selected from the group consisting of aluminum, silver, copper, gold, nickel, palladium, and platinum.

The metallization layer can just as well have a multi-layer structure. Accordingly, it can be preferred that at least one surface of the components to be connected comprises a metallization layer made of multiple layers that comprise the pure metals and/or alloys specified above.

In the method according to the invention, at least two components are being connected to each other through sintering.

For this purpose, the two components are first made to contact each other. The contacting is effected by the metal sintering preparation according to the invention. For this purpose, an arrangement is provided in which metal sintering preparation according to the invention is situated between each pair of the at least two components.

Accordingly, if two components, i.e., component 1 and component 2, are to be connected to each other, the metal sintering preparation according to the invention is situated between component 1 and component 2 before the sintering process. On the other hand, it is conceivable to connect more than two components to each other. For example three components, i.e., component 1, component 2, and component 3, can be connected to each other in an appropriate manner such that component 2 is situated between component 1 and component 3. In this case, the metal sintering preparation according to the invention is situated between both component 1 and component 2 as well as between component 2 and component 3.

The individual components are present in a sandwich arrangement and are being connected to each other. A sandwich arrangement shall be understood to mean an arrangement in which two components are situated one above the other with the two components being arranged essentially parallel with respect to each other.

The arrangement of at least two components and metal sintering preparation according to the invention, wherein the metal sintering preparation is situated between two components of this arrangement, can be produced according to any method known according to the prior art.

Preferably, firstly, at least one surface of a component 1 is provided with the metal sintering preparation according to the invention. Then, another component 2 is placed by one of its surfaces on the metal sintering preparation that has been applied to the surface of component 1.

The metal sintering preparation according to the invention can be applied onto the surface of a component by conventional methods, such as by dispensing technique, like dispensing or jet dispensing, or printing methods such as screen printing or stencil printing or, just as well, by other application techniques such as spray application, pin transfer or dipping.

Following the application of the metal sintering preparation according to the invention, it is preferable to contact the surface of this component that has been provided with the metal sintering preparation to a surface of the component to be connected thereto by the metal sintering preparation. Accordingly, a layer of the metal sintering preparation according to the invention is situated between the components to be connected.

Preferably, the thickness of the wet layer between the components to be connected is in the range of 20 to 100 μm. In this context, thickness of the wet layer shall be understood to mean the distance between the opposite surfaces of the components to be connected prior to drying, if any, and prior to sintering. The preferred thickness of the wet layer depends on the method selected for applying the metal sintering preparation. If the metal sintering preparation is applied, for example, by a screen printing method, the thickness of the wet layer can preferably be 20 to 50 μm. If the metal sintering preparation is applied by stencil printing, the preferred thickness of the wet layer can be in the range of 20 to 100 μm. The preferred thickness of the wet layer in the dispensing technique can be in the range of 10 to 100 μm.

As an option, a drying step can be performed prior to the sintering, i.e., the organic solvent is removed from the applied metal sintering preparation. According to a preferred embodiment, the fraction of organic solvent in the metal sintering preparation after drying is, for example, 0 to 5% by weight with respect to the original fraction of organic solvent in the metal sintering preparation according to the invention, i.e., in the metal sintering preparation ready for application. In other words, according to this preferred embodiment, for example 95 to 100% by weight of the organic solvent that is originally present in the metal sintering preparation according to the invention are removed during drying.

If drying takes place in a sintering process without pressure, the drying can proceed after producing the arrangement, i.e., after contacting the components to be connected. If drying takes place in a sintering process involving the application of pressure, the drying can just as well proceed after application of the metal sintering preparation onto the at least one surface of the component and before contacting to the component to be connected.

Preferably, the drying temperature is in the range of 100 to 180° C.

Obviously, the drying time depends on the composition of the metal sintering preparation according to the invention and on the size of the connecting surface of the arrangement to be sintered. Common drying times are in the range of 5 to 45 minutes.

The arrangement consisting of the at least two components and metal sintering preparation situated between the components is finally subjected to a sintering process.

The actual sintering proceeds at a temperature of, for example, 200 to 280° C. in a process either with or without pressure.

The process pressure in pressure sintering is preferably less than 30 MPa and more preferably less than 5 MPa. For example, the process pressure is in the range of 1 to 30 MPa and more preferably is in the range of 1 to 5 MPa.

The sintering time is, for example, in the range of 2 to 90 minutes, for example in the range of 2 to 5 minutes in pressure sintering and, for example, in the range of 15 to 90 minutes in sintering without pressure. In the scope of the invention, the sintering time shall be understood to be the period of time during the process of sintering during which the metal sintering preparation to be sintered is exposed to a temperature>180° C.

The sintering process can take place in an atmosphere that is not subject to any specific limitations. Accordingly, on the one hand, the sintering can take place in an atmosphere that contains oxygen. On the other hand, it is just as feasible that the sintering takes place in an oxygen-free atmosphere. In the scope of the invention, an oxygen-free atmosphere shall be understood to mean an atmosphere whose oxygen content is no more than 100 ppm, preferably no more than 10 ppm, and even more preferably no more than 0.1 ppm.

The sintering takes place in a conventional suitable apparatus for sintering, in which the above-mentioned process parameters can be set.

The invention is illustrated through examples in the following, though these may not be construed so as to limit the invention in any way or form.

### EXAMPLES

The following silver flakes each comprising a fatty acid coating were used in the examples:

| | Tamped | Specific | |
|---|---|---|---|
| | density S | surface O | Product S · O |
| Silver flakes | [g/cm³] | [m²/g] | [cm⁻¹] |
| 406-14 from Metalor | 3.0 | 1.72 | 51600 |
| 406-3 from Metalor | 3.1 | 1.80 | 55800 |
| Ferro SF 30 from Ferro | 3.3 | 1.80 | 59400 |
| Ferro EG-ED from Ferro | 4.6 | 0.15 | 6900 |
| Silflake 160 from Technic Inc. | 2.5 | 0.95 | 23750 |
| 690-3 from Metalor | 3.3 | 2.08 | 68640 |

### 1. Production of Silver Sintering Preparations:

Firstly, silver sintering preparations 1-4, 5-8 according to the invention and reference preparations V1-V3 were produced by mixing the individual ingredients according to the following table. All amounts given are in units of % by weight.

| | Silver sintering preparation | | | | | | | | | | |
|---|---|---|---|---|---|---|---|---|---|---|---|
| | 1 | 2 | 3 | 4 | V1 | 5 | 6 | 7 | 8 | V2 | V3 |
| 406-14 | | 60 | | 41 | | | 85 | | | | |
| 406-3 | 82 | | | | | | | | 55 | | |
| SF 30 | | | 82 | | | | | | | | |
| EG-ED | | | | | | | | | | 85 | |
| Silflake 160 | | 22 | | | 82 | 42.5 | | | 30 | | 60 |
| 690-3 | | | | 41 | | 42.5 | | 85 | | | 25 |
| Silver | 4 | 4 | 4 | 4 | 4 | | | | | | |
| carbonate | | | | | | | | | | | |
| α-Terpineol | 8 | 8 | 8 | 8 | 8 | 8 | 8 | 8 | 8 | 8 | 8 |
| 1-Tridecanol | 6 | 6 | 6 | 6 | 6 | 7 | 7 | 7 | 7 | 7 | 7 |
| Total | 100 | 100 | 100 | 100 | 100 | 100 | 100 | 100 | 100 | 100 | 100 |

### 2. Application and Pressure-Free Sintering of Silver Sintering Preparations 1-4 and V1:

The respective silver sintering preparation was applied by dispensing onto the silver surface of a DCB substrate provided with a silver layer and/or onto the copper surface of a DCB substrate with the thickness of the wet layer being 50 μm. Then, the applied silver sintering preparation was contacted without prior drying to a silicon chip having a silver contact surface (2·2 mm²). The subsequent pressure-free sintering took place according to the following heating profile in a nitrogen atmosphere (<100 ppm of oxygen): The contact site was heated continuously over a period of 60 minutes to 200° C., then heated to 230° C. over the course of five minutes, and maintained at this temperature for 30 minutes. Then, this was cooled steadily to 30° C. over the course of 50 minutes.

After sintering, the bonding was determined by testing the shear strength. In this context, the components were sheared off with a shearing chisel at a rate of 0.3 mm/s at 260° C. The force was measured by a load cell (DAGE 2000 device made by DAGE, Germany).

The following table shows the results obtained:

| | 1 | 2 | 3 | 4 | V1 |
|---|---|---|---|---|---|
| Product S · O [cm⁻¹] | 55800 | 44128 | 59400 | 60120 | 23750 |
| Adhesion on Cu surface [N/mm²] | 23 | 16 | 22 | 45 | 5 |
| Adhesion on Ag surface [N/mm²] | 28 | 24 | 29 | 31 | 6 |

### 3. Application and Pressure Sintering of Silver Sintering Preparations 5-8, V2, and V3:

The respective silver sintering preparation was applied by stencil printing onto the silver surface of a DCB substrate provided with a silver layer and/or onto the copper surface of a DCB substrate with the thickness of the wet layer being 50 μm. Subsequently, the silver sintering preparation thus applied was dried for 20 minutes at 120° C. Then, a silicon chip having a silver contact surface (2·2 mm²) was applied at 160° C. and then the sintering proceeded with a pressure sintering press for 3 minutes at 230° C. and a pressure of 10 MPa.

The adhesion was determined as in test series 2:

| | 5 | 6 | 7 | 8 | V2 | V3 |
|---|---|---|---|---|---|---|
| Product S•O [cm⁻¹] | 46195 | 51600 | 68640 | 44488 | 6900 | 36953 |
| Adhesion on Cu surface | 34 | 43 | 49 | 27 | 0 | 2 |
| [N/mm²] | | | | | | |
| Adhesion on Ag surface | 18 | 28 | 31 | 21 | 0 | 5 |
| [N/mm²] | | | | | | |

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims

We claim:

1. A metal sintering preparation comprising: (A) 50 to 90% by weight of silver that is present in the form of particles, wherein the particles comprise a coating containing at least one organic compound, (B) 6 to 50% by weight organic solvent, (C) 0 to 12% by weight of at least one metal precursor, (D) 0 to 10% by weight of at least one sintering aid, and (E) 0 to 15% by weight of one or more further ingredients selected from dispersion agents, surfactants, de-foaming agents, binding agents, polymers and/or viscosity-controlling rheological agents,
wherein a mathematical product of tamped density and specific surface of the metal particles of component (A) is in a range of 40,000 to 70,000 cm⁻¹ and wherein at least 70% by weight of the particles are present in the form of flakes.

2. The metal sintering preparation according to claim 1, wherein the mathematical product of tamped density and specific surface of the metal particles of component (A) is in the range of 50,000 to 70,000 cm⁻¹.

3. The metal sintering preparation according to claim 1, comprising one, two or more different types of metal particles.

4. The metal sintering preparation according to claim 1, wherein the at least one organic compound is selected from the group consisting of free fatty acids, fatty acid salts, and fatty acid esters.

5. A method for the connecting of components comprising (a) providing a sandwich arrangement which comprises at least (a1) one component 1, (a2) one component 2, and (a3) one metal sintering preparation according to claim 1 that is situated between component 1 and component 2, and (b) sintering the sandwich arrangement.

6. The method according to claim 5, wherein at least one of components 1 and 2 comprises an aluminum contact surface or copper contact surface by which the sandwich arrangement is implemented.

7. The method according to claim 5, wherein the sintering is performed while applying pressure or without pressure.

8. The method according to claim 5, wherein the components are parts that are used in electronics.
